(19) United States
(12) Patent Application Publication
(10) Pub. No.: US 2025/0240893 A1
(43) Pub. Date: Jul. 24, 2025

(54) PACKAGE STRUCTURE

(71) Applicant: Advanced Semiconductor Engineering, Inc., Kaohsiung (TW)

(72) Inventors: Che-Neng LIU, Kaohsiung (TW); Guo-Cheng LIAO, Kaohsiung (TW)

(73) Assignee: Advanced Semiconductor Engineering, Inc., Kaohsiung (TW)

(21) Appl. No.: 18/418,125

(22) Filed: Jan. 19, 2024

(51) Int. Cl. H05K 1/18; H04R 1/04; H05K 3/32

(52) U.S. Cl. CPC H05K 1/182; H04R 1/04; H05K 3/32; H05K 2201/10151; H05K 2203/049

(57) ABSTRACT

A package structure is provided. The package structure includes a substrate, a chip, and an adhesive layer. The substrate defines a through hole. The chip is disposed in the through hole and has a top surface and a bottom surface opposite to the top surface. The adhesive layer connects the chip to the through hole. The top surface and the bottom surface of the chip are exposed by the adhesive layer, and the chip is protruded beyond the substrate.

### BACKGROUND

### 1. Technical Field

The present disclosure relates generally to a package structure.

### 2. Description of the Related Art

Currently, for manufacturing a package structure including a chip or component with input/output (I/O) terminals on opposite sides, a ceramic substrate may be manufactured to provide a specific structure for the chip or component to be disposed therein, such that the I/O terminals on opposite sides of the chip or component can be exposed by the ceramic substrate for electrical connection. However, the cost and the difficulty for manufacturing the ceramic substrate with the specific structure may be relatively high, and the brittle texture of the ceramic substrate may render the ceramic substrate relatively fragile and thus reducing the yield.

### SUMMARY

In one or more arrangements, a package structure includes a substrate, a chip, and an adhesive layer. The substrate defines a through hole. The chip is disposed in the through hole and has a top surface and a bottom surface opposite to the top surface. The adhesive layer connects the chip to the through hole. The top surface and the bottom surface of the chip are exposed by the adhesive layer, and the chip is protruded beyond the substrate.

In one or more arrangements, a package structure includes a substrate and a chip. The substrate defines a through hole. The chip is disposed in the through hole. A first gap between the chip and a sidewall of the through hole includes an upper portion and a lower portion having different widths.

In one or more arrangements, a package structure includes a substrate and a chip. The substrate defines a through hole extending between a top surface and a bottom surface of the substrate. The chip is disposed in the through hole. The chip has a top surface and a bottom surface opposite to the top surface, wherein the top surface of the chip is protruded beyond the top surface of the substrate, and the bottom surface of the chip is substantially aligned with the bottom surface of the substrate.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a top view of a package structure in accordance with some arrangements of the present disclosure.

FIG. 1C is a top view of a package structure in accordance with some arrangements of the present disclosure.

FIG. 1D is a bottom view of a package structure in accordance with some arrangements of the present disclosure.

FIG. 2A is a cross-section of a package structure in accordance with some arrangements of the present disclosure.

FIG. 2B is a cross-section of a package structure in accordance with some arrangements of the present disclosure.

FIG. 3A, FIG. 3B, FIG. 3C, FIG. 3D, FIG. 3E, FIG. 3F, and FIG. 3G illustrate various stages of an exemplary method for manufacturing a package structure in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

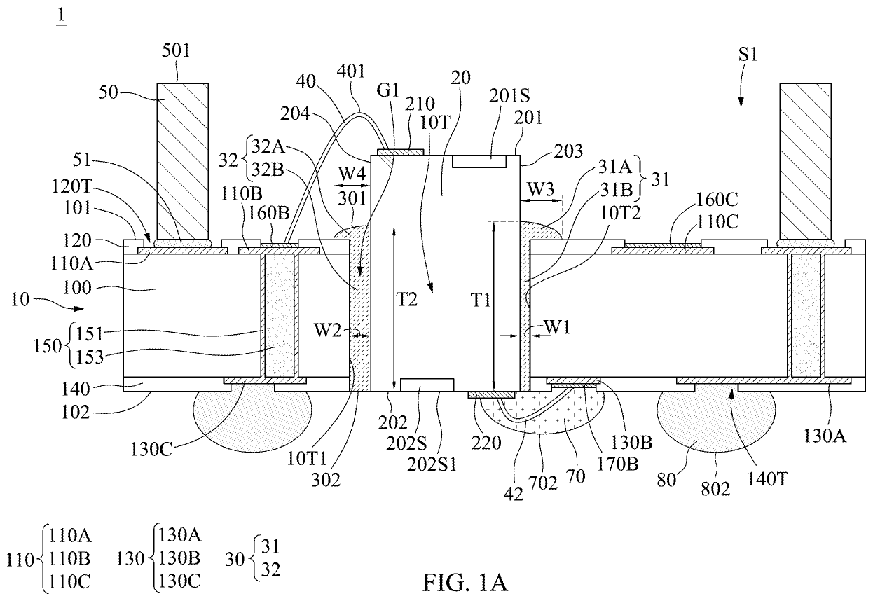

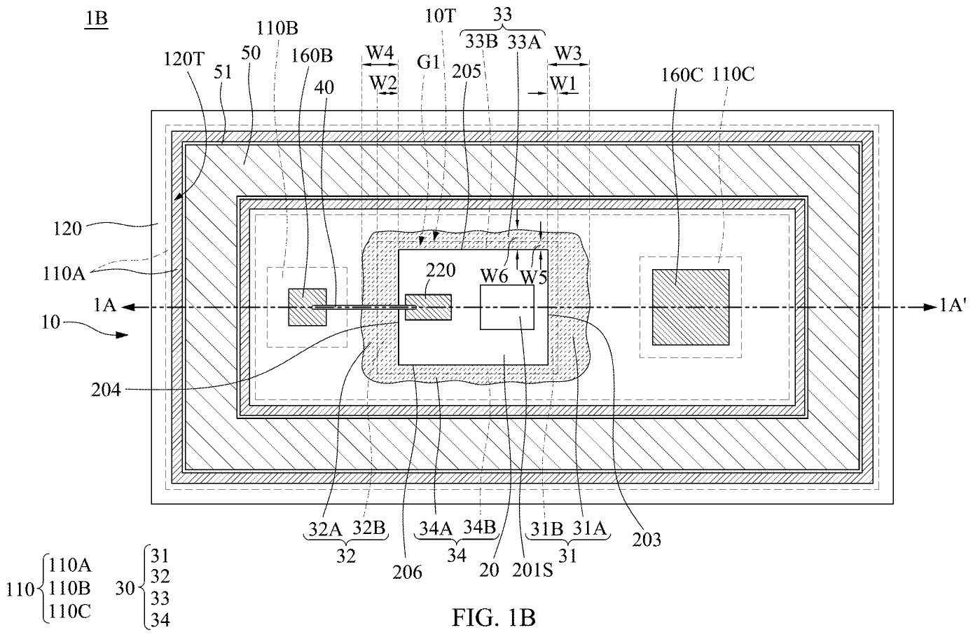

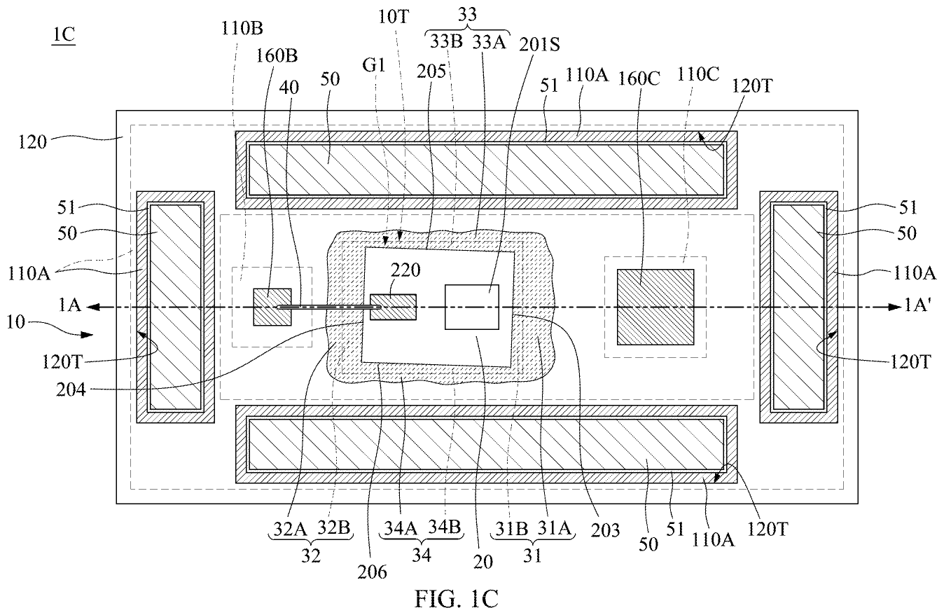

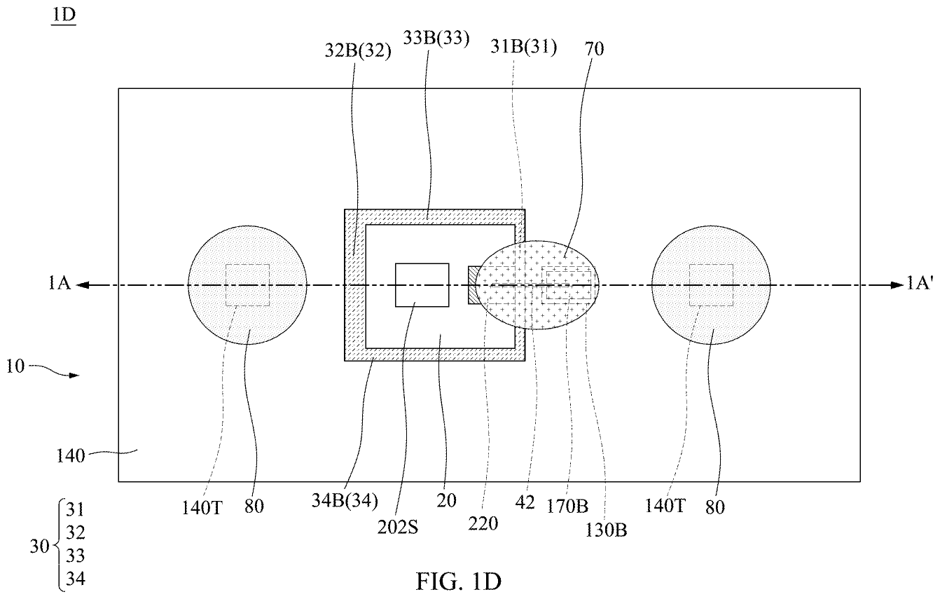

FIG. 1A is a cross-section of a package structure 1 in accordance with some arrangements of the present disclosure. The package structure 1 may include a substrate 10, a chip 20, an adhesive layer 30, conductive wires 40 and 42, a spacer structure 50, an adhesive element 51, a protective element 70, and electrical contacts 80.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, which may include a plurality of conductive traces and/or conductive vias. The interconnection structure may include a redistribution layer (RDL) and/or a grounding element. In some arrangements, the substrate 10 may include an organic substrate or a leadframe. In some arrangements, the substrate 10 may include a ceramic material or a metal plate. In some arrangements, the substrate 10 may include a two-layer substrate which includes a core layer and a conductive material and/or structure disposed on an upper surface and a bottom surface of the substrate. The substrate 10 may include a semiconductor wafer or an electronic component. The electronic component may be a chip or a die including a semiconductor substrate, one or more integrated circuit devices, and one or more overlying interconnection structures therein. The integrated circuit devices may include active devices such as transistors and/or passive devices such resistors, capacitors, inductors, or a combination thereof. In some arrangements, the substrate 10 may include one or more conductive elements, surfaces, contacts, or pads.

In some arrangements, the substrate 10 has a surface 101 (also referred to as “a top surface” or “an upper surface”) and a surface 102 (also referred to as “a bottom surface” or “a lower surface”) opposite to the surface 101. In some arrangements, the substrate 10 defines a through hole 10T. In some arrangements, the through hole 10T extends between the surface 101 (or the top surface) and the surface 102 (or the bottom surface) of the substrate 10. In some arrangements, the through hole 10T includes at least sidewalls 10T1 and 10T2 in a cross-sectional view perspective.

In some arrangements, the substrate 10 includes a base layer 100, circuit layers 110 and 130, dielectric layers 120 and 140, and one or more conductive vias 150. In some arrangements, the base layer 100 may be or include a semiconductor substrate or other suitable materials or elements included in the substrate 10 as described above. In some arrangements, the circuit layer 110 is adjacent to the surface 101 (or the top surface), and the circuit layer 130 is adjacent to the surface 102 (or the bottom surface). In some arrangements, the circuit layer 110 may be or include conductive pads, conductive layers, conductive patterns, conductive portions, or the like. In some arrangements, the circuit layer 110 includes portions 110A, 110B, and 110C. The portions 110A, 110B, and 110C may be electrically disconnected from one another. In some arrangements, the circuit layer 110 further includes protective films 160B and 160C on the portions 110B and 110C, respectively. The protective film may be or include a metal finish layer, such as NiAu alloy or other suitable materials. In some arrangements, the circuit layer 130 may be or include conductive pads, conductive layers, conductive patterns, conductive portions, or the like. In some arrangements, the circuit layer 130 includes portions 130A, 130B, and 130C. The portions 130A, 130B, and 130C may be electrically disconnected from one another. In some arrangements, the circuit layer 130 further includes a protective film 170B on the portion 130B. The protective film may be or include a metal finish layer, such as NiAu alloy or other suitable materials.

In some arrangements, the dielectric layers 120 and 140 are disposed on the circuit layers 110 and 130, respectively. In some arrangements, the dielectric layer 120 has one or more openings 120T exposing portions of the circuit layer 110. In some arrangements, the portion 110A and the protective films 160B and 160C are exposed by the openings 120T. In some arrangements, the dielectric layer 140 has one or more openings 140T exposing portions of the circuit layer 130. In some arrangements, the portions 130A and 130C and the protective film 170B are exposed by the openings 140T. In some arrangements, the conductive via 150 electrically connects the surface 101 to the surface 102 of the substrate 10. In some arrangements, the conductive vias 150 penetrate the base layer 100. In some arrangements, the conductive via 150 includes a conductive liner 151 and an insulative filling layer 153 (e.g., a dielectric layer). In some arrangements, one of the conductive vias 150 is electrically connected to the portion 110A of the circuit layer 110 and the portion 130A of the circuit layer 130, and another one of the conductive vias 150 is electrically connected to the portion 110B of the circuit layer 110 and the portion 130C of the circuit layer 130.

The chip 20 may be disposed in the through hole 10T of the substrate 10. In some arrangements, the chip 20 has a surface 201 (also referred to as “a top surface” or “an upper surface”), a surface 202 (also referred to as “a bottom surface” or “a lower surface”) opposite to the surface 201, and at least surfaces 203 and 204 (also referred to as “lateral side surfaces”) extending between the surface 201 and the surface 202. In some arrangements, the chip 20 is protruded out of the substrate 10. In some arrangements, the chip 20 is protruded out of the through hole 10T. In some arrangements, the surface 201 (or the top surface) of the chip 20 is protruded beyond the surface 101 (or the top surface) of the substrate 10, and the surface 202 (or the bottom surface) of the chip 20 is substantially aligned with the surface 102 (or the bottom surface) of the substrate 10. In some arrangements, the surface 201 of the chip 20 and the surface 101 of the substrate 10 are at different elevations. In some arrangements, the lateral side surface (e.g., the surfaces 203 and 204) of the chip 20 is separated from or spaced apart from the sidewall of the through hole 10T by a gap G1. In some arrangements, a thickness of the chip 20 is greater than a thickness of the substrate 10. In some arrangements, a thickness of the chip 20 is greater than a depth of the through hole 10T. The chip 20 may be or include a sensor. The sensor may be or include a micro-electromechanical system (MEMS) sensor, a temperature sensor, a pressure sensor, a humidity sensor, an inertial force sensor, a chemical species sensor, a magnetic field sensor, or a combination thereof.

In some arrangements, the chip 20 includes a sensing element 201S adjacent to the surface 201 and a sensing element 202S adjacent to the surface 202. In some arrangements, at least one of the sensing elements 201S and 202S is or includes an acoustic sensor. In some arrangements, the sensing element 201S is exposed by the surface 201 of the chip 20, and the sensing element 202S is exposed by the surface 202 of the chip 20. In some arrangements, the sensing elements 201S and 202S are exposed by the substrate 10. In some arrangements, a surface 202S1 of the sensing element 202S is substantially aligned with the surface 102 of the substrate 10.

In some arrangements, the chip 20 includes at least pads 210 and 220 (also referred to as “conductive pads” or “conductive terminals”). In some arrangements, the pad 210 is on the surface 201 (or the top surface) of the chip 20, and the pad 220 is on the surface 202 (or the bottom surface) of the chip 20. In some arrangements, the pad 210 is protruded beyond the surface 201 of the chip 20, and the pad 220 is protruded beyond the surface 202 of the chip 20. In some arrangements, the pad 210 is electrically connected to the surface 101 of the substrate 10, and the pad 220 is electrically connected to the surface 102 of the substrate 10.

The adhesive layer 30 may be disposed between the chip 20 and the substrate 10. In some arrangements, the adhesive layer 30 has a surface 301 (also referred to as “a top surface” or “an upper surface”) and a surface 302 (also referred to as “a bottom surface” or “a lower surface”) opposite to the surface 301. In some arrangements, the adhesive layer 30 connects the chip 20 to the through hole 10T. In some arrangements, the adhesive layer 30 connects the chip 20 to the sidewall (e.g., the sidewalls 10T1 and 10T2) of the through hole 10T. In some arrangements, the surface 201 (or the top surface) and the surface 202 (or the bottom surface) of the chip 20 are exposed by the adhesive layer 30. In some arrangements, the sensing elements 201S and 202S are exposed by the adhesive layer 30. In some arrangements, the surface 202S1 of the sensing element 202S is substantially aligned with the surface 302 of the adhesive layer 30. In some arrangements, the adhesive layer 30 may be or include an underfill. The underfill may include an epoxy resin, a molding compound (e.g., an epoxy molding compound or other molding compound), polyimide, a phenolic compound or material, a material including a silicone dispersed therein, or a combination thereof.

In some arrangements, the adhesive layer 30 includes at least portions 31 and 32. In some arrangements, the portion 31 is between the surface 203 (or the lateral side surface) of the chip 20 and the sidewall 10T1 of the through hole 10T, and the portion 32 is between the surface 204 (or the lateral side surface) of the chip 20 and the sidewall 10T2 of the through hole 10T. In some arrangements, the portion 31 and the portion 32 have different widths. For example, a width W1 of the portion 31 may be less than a width W2 of the portion 32. In some arrangements, the portion 31 and the portion 32 have different thicknesses. For example, a thickness T1 of the portion 31 may be greater than a thickness T2 of the portion 32. In some arrangements, the adhesive layer 30 is partially extending over at least a portion of the surface 101 of the substrate 10.

In some arrangements, the portion 31 of the adhesive layer 30 includes a lower part 31B and an upper part 31A. In some arrangements, the upper part 31A extends over at least a portion of the surface 101 of the substrate 10. In some arrangements, the upper part 31A protrudes out of the through hole 10T of the substrate 10. In some arrangements, the upper part 31A partially covers the surface 101 (or the top surface) of the substrate 10. In some arrangements, the lower part 31B and the upper part 31A have different widths. For example, a width W1 of the lower part 31B may be less than a width W3 of the upper part 31A. In some arrangements, the portion 32 of the adhesive layer 30 includes a lower part 32B and an upper part 32A. In some arrangements, the upper part 32A protrudes out of the through hole 10T of the substrate 10. In some arrangements, the upper part 32A partially covers the surface 101 (or the top surface) of the substrate 10. In some arrangements, the lower part 32B and the upper part 32A have different widths. For example, a width W3 of the lower part 32B may be less than a width W4 of the upper part 32A. In some arrangements, the upper part 31A and the upper part 32A have different widths. For example, the upper part 31A may be wider than the upper part 32A. For example, the width W3 of the upper part 31A may be greater than the width W4 of the upper part 32A. In some arrangements, the lower part 31B and the lower part 32B have different widths. For example, the lower part 31B may be narrower than the lower part 32B. For example, the width W1 of the lower part 31B may be less than the width W2 of the lower part 32B.

In some arrangements, the lower parts 31B and 32B may collectively form a lower portion of the adhesive layer 30, and the lower portion is filled in the gap G1 between the chip 20 and the sidewall of the through hole 10T. In some arrangements, the upper parts 31A and 32A may collectively form an upper portion of the adhesive layer 30, and the upper portion partially covers the surface 101 (or the top surface) of the substrate 10. In some arrangements, the upper portion (e.g., the upper parts 31A and 32A) of the adhesive layer 30 has a non-uniform top surface (e.g., the surfaces 301 and 301′). In some arrangements, the upper portion (e.g., the upper parts 31A and 32A) of the adhesive layer 30 has a curved surface (e.g., the surfaces 301 and 301′) in a cross-sectional view perspective.

The conductive wire 40 may connect the chip 20 to the substrate 10. In some arrangements, the chip 20 is electrically connected to the substrate 10 through the conductive wire 40. In some arrangements, the conductive wire 40 and a portion of the chip 20 protruded beyond the surface 101 of the substrate 10 are exposed by the adhesive layer 30. In some arrangements, the conductive wire 40 is exposed by the upper portion (e.g., the upper parts 31A and 32A) of the adhesive layer 30. In some arrangements, the conductive wire 40 electrically connects the surface 201 of the chip 20 to the surface 101 of the substrate 10. In some arrangements, the pad 210 of the chip 20 is electrically connected to the surface 101 of the substrate 10 by the conductive wire 40. In some arrangements, the conductive wire 40 electrically connects the pad 210 of the chip 20 to the protective film 160B and the portion 110B of the circuit layer 110 of the substrate 10.

The conductive wire 42 may connect the chip 20 to the substrate 10. In some arrangements, the chip 20 is electrically connected to the substrate 10 through the conductive wire 42. In some arrangements, the conductive wire 42 is exposed by the adhesive layer 30. In some arrangements, the conductive wire 42 electrically connects the surface 202 of the chip 20 to the surface 102 of the substrate 10. In some arrangements, the pad 220 of the chip 20 is electrically connected to the surface 102 of the substrate 10 by the conductive wire 42. In some arrangements, the conductive wire 42 electrically connects the pad 220 of the chip 20 to the protective film 170B and the portion 130B of the circuit layer 130 of the substrate 10. In some arrangements, a curvature of the conductive wire 40 is greater than a curvature of the conductive wire 42. In some arrangements, a curvature change of the conductive wire 40 is greater than a curvature change of the conductive wire 42. The term “curvature change” used herein may indicate a change in heights or elevations of the wire within a predetermined horizontal distance. The term “curvature change” may also reflect the slope of the wire. The conductive wires 40 and 42 in combination may be referred to as a wire-bonding structure. The wire-bonding structure connects at least one of the surfaces 201 and 202 of the chip to at least one of the surfaces 101 and 102 of the substrate.

The spacer structure 50 may be disposed around the conductive wire 40. In some arrangements, an elevation of a top surface 501 of the spacer structure 50 is higher than an elevation of a top end 401 of the conductive wire 40 with respect to the surface 101 of the substrate 10. In some arrangements, the spacer structure 50 is disposed on the surface 101 of the substrate 10 and configured to protect the chip 20 from being damaged. In some arrangements, the spacer structure 50 is disposed on the surface 101 of the substrate 10 and defines a space S1 for accommodating the conductive wire 40 and a portion of the chip 20 protruded beyond the surface 101 of the substrate 10. In some arrangements, the spacer structure 50 is connected to (or electrically connected to) ground through the conductive via 150. The spacer structure 50 may serve as a shielding element configured to reduce electromagnetic interference (EMI). In some arrangements, the spacer structure 50 may be referred to as or include a spacer, a metal spacer, an interposer, or the like. The spacer structure 50 may be or include a metal frame or a metal wall structure. In some embodiments, the spacer structure 50 is made of or include a conductive material including, for example, aluminum (Al), copper (Cu), chromium (Cr), tin (Sn), gold (Au), silver (Ag), nickel (Ni) or stainless steel, or a mixture, an alloy, or other combination thereof.

The adhesive element 51 may connect the spacer structure 50 to the substrate 10. In some arrangements, the adhesive element 51 is at least partially within the opening 120T of the dielectric layer 120. In some arrangements, the adhesive element 51 is formed of or includes a conductive material. The adhesive element 51 may be or include a conductive adhesive, e.g., a silver paste or a silver gel. The adhesive element 51 may be or include a solder material. In some arrangements, the adhesive element 51 electrically connects the spacer structure 50 to the portion 110A of the circuit layer 110.

The protective element 70 may encapsulate the conductive wire 42 and a portion of the pad 220. In some arrangements, the protective element 70 further covers at least a portion of the protective film 170B. The protective element 70 may include an encapsulant. The encapsulant may include an epoxy resin having fillers, a molding compound (e.g., an epoxy molding compound or other molding compound), polyimide, a phenolic compound or material, a material with a silicone dispersed therein, or a combination thereof. In some arrangements, the protective element 70 may be or include a sealing gel. In some arrangements, the protective element 70 may be or include a sealant.

The electrical contacts 80 may be disposed on the surface 102 of the substrate 10. In some arrangements, an elevation of a bottom surface 802 of the electrical contacts 80 is lower than an elevation of a bottom surface 702 of the protective element 70 with respect to the surface 102 of the substrate 10. In some arrangements, the electrical contacts 80 are electrically connected to the circuit layer 130 of the substrate 10. In some embodiments, the electrical contacts 80 include controlled collapse chip connection (C4) bumps, a ball grid array (BGA), or a land grid array (LGA). The spacer structure 50 and the electrical contacts 80 may be collectively referred to as a protective structure. The protective structure may surround the wire-bonding structure. In some arrangements, the protective structure is configured to prevent the wire-bonding structure from impacts from outside of the package structure. In some arrangements, the substrate 10 and the protective structure (e.g., the spacer structure 50) on the surface 101 of the substrate 10 collectively define the space S1, and the surface 201 of the chip 20 is exposed to the space S1. In some arrangements, a top end (e.g., the top end 401) of the wire-bonding structure is lower than a top surface (e.g., the top surface 501) of the protective structure.

The conductive layers, pads, pillars, portions, vias, liners, and/or terminals may independently include a conductive material such as a metal or metal alloy. Examples include Au, Ag, Al, Cu, or an alloy thereof. The dielectric layers may independently include an organic material, a solder mask, PI, an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like.

In some cases where a ceramic substrate is manufactured to provide a specific structure for a chip to be disposed therein, such that the I/O terminals on opposite sides of the chip can be exposed by the ceramic substrate for electrical connection. However, the cost and the difficulty for manufacturing the ceramic substrate with the specific structure may be relatively high, and the brittle texture of the ceramic substrate may render the ceramic substrate relatively fragile and thus reducing the yield. To solve the above problems, a plastic substrate including a specific structure to the chip to be disposed therein may be provided. The plastic substrate may be formed by the following steps: a top cavity and a bottom cavity may be formed from the top surface and the bottom surface of the plastic substrate, respectively, to connect the top cavity and the bottom cavity to form a through hole with a platform defined by the cavities in the plastic substrate, such that the chip may be disposed on the platform in the through hole of the plastic substrate. However, it is relatively difficult to precisely control the depths of the top cavity and the bottom cavity during the two-step cavity-forming process, and thus the variations in depths of the cavities may render the as-formed platform to have a non-uniform elevation, which may reduce the yield as well.

According to some arrangements of the present disclosure, the chip is disposed in the through hole of the substrate and connected to the sidewall of the through hole. The process for forming the through hole is relatively easy and simplified (e.g., by a one-step drilling operation), the issue of difficulty in controlling the depths of multiple cavities can be omitted, thus the yield can be increased, and the cost can be reduced. In addition, both sides or surfaces of the chip can be exposed by opposite openings of the through hole, such that both sides or surfaces of the chip can be electrically connected to conductive elements (e.g., conductive wires).

In addition, when the chip is disposed on a platform in the through hole of the substrate, the platform that supports the bottom surface of the chip may partially cover the bottom surface of the chip and thus reduce the area for electrical connection (e.g., connection to bonding wires). Moreover, since the bottom surface of the chip is supported by the platform in the through hole, the bonding wire that connects to the bottom surface of the chip is disposed in the through hole, which increases the processing difficulty and thus reduces the yield. In contrast, according to some arrangements of the present disclosure, the chip is adhered to the sidewall of the through hole, the opposite sides or surfaces of the chip can be entirely exposed for electrical connection (e.g., for connecting to conductive wires), and thus the available areas for electrical connection on opposite sides or surfaces of the chip can be enlarged. Moreover, the opposite surfaces of the chip are exposed by the substrate, such that the bonding areas of the chip are exposed by the substrate as well, and thus the conductive wires (e.g., bonding wires) that connect to the bonding areas of the chip can be disposed outside of the through hole, which reduces the processing difficulty and thus increases the yield. Furthermore, since the bonding areas are exposed by the substrate, the alignment accuracy can be improved when connecting the conductive wires to the bonding area, thus the positional offset errors can be reduced, and the yield can be further increased.

Furthermore, according to some arrangements of the present disclosure, the chip is adhered to the sidewall of the through hole by an adhesive layer. The material of the adhesive layer may flow into the relatively narrow gap between the chip and the sidewall of the through hole and then be cured to form the adhesive layer during the manufacturing process, and thus the gap can be relatively small, such that the overall size of the package structure can be reduced. Moreover, the material of the adhesive layer may overflow to partially cover the top surface of the substrate, such that the contact area between the chip and the substrate can be increased without increasing the package size, which is further advantageous to increasing the reliability of the package structure and the yield.

Moreover, according to some arrangements of the present disclosure, the spacer structure is taller than the chip and the conductive wire over the top surface of the substrate, such that the spacer structure can protect the chip and the conductive wire from being damaged. In addition, the spacer structure may be further electrically connected to ground, such that the spacer structure can further serve as an EMI shielding element for the chip without disposing or installing additional EMI shielding structures. Therefore, the electrical performance of the package structure can be improved without increasing the package size.

Furthermore, according to some arrangements of the present disclosure, the electrical contacts are taller than the protective element and the conductive wire under the bottom surface of the substrate. Therefore, in addition to electrically connecting to external components, the electrical contacts can further protect the protective element and the conductive wire from being damaged. Therefore, the reliability of the package structure can be improved without increasing the package size.

FIG. 1B is a top view of a package structure 1B in accordance with some arrangements of the present disclosure. In some arrangements, FIG. 1B shows a top view of the package structure 1 illustrated in FIG. 1A. In some arrangements, FIG. 1A shows a cross-section along a line 1A-1A′ in FIG. 1B.

In some arrangements, the adhesive layer 30 includes portions 31, 32, 33, and 34. The adhesive layer 30 may have a ring shape from a top view perspective. The adhesive layer 30 may have an irregular edge profile from a top view perspective. The adhesive layer 30 may have a non-uniform edge profile from a top view perspective. The portions 31, 32, 33, and 34 may be directly connected to one another. In some arrangements, the portion 33 is between the surface 205 (or the lateral side surface) of the chip 20 and a sidewall of the through hole 10T, and the portion 34 is between the surface 206 (or the lateral side surface) of the chip 20 and a sidewall of the through hole 10T. Two or more of the portions 31, 32, 33, and 34 may have different widths. In some arrangements, in a top view perspective, the chip has a long side (e.g., the surface 205) and a short side (e.g., the surface 204), the portion 33 adjacent to the long side of the chip 20 and the portion 32 adjacent to the short side of the chip 20 have different widths. In some arrangements, the width W4 the upper part 32A of the portion 32 is greater than a width W6 of the upper part 33A of the portion 33. In some arrangements, the width W2 the lower part 32B of the portion 32 is greater than a width W5 of the lower part 33B of the portion 33. The portion 33 may have an upper part 33A and a lower part 33B having cross-sectional structures similar to those of the upper part and the lower part of the portion 31 or the portion 32. The portion 34 may have an upper part 34A and a lower part 34B having cross-sectional structures similar to those of the upper part and the lower part of the portion 31 or the portion 32.

In some arrangements, the adhesive layer 30 is around the chip 20. In some arrangements, the adhesive layer 30 surrounds the chip 20 in a top view perspective. In some arrangements, the gap G1 surrounds the chip 20. In some arrangements, the portion 110A of the circuit layer 110 surrounds the chip 20, the adhesive layer 30, and the gap G1. In some arrangements, the opening 120T of the dielectric layer 120 surrounds the chip 20, the adhesive layer 30, and the gap G1. In some arrangements, the portion 110A is partially exposed by the opening 120T. In some arrangements, the spacer structure 50 surrounds the chip 20, the adhesive layer 30, and the gap G1. In some arrangements, the adhesive element 51 surrounds the chip 20, the adhesive layer 30, and the gap G1.

FIG. 1C is a top view of a package structure 1C in accordance with some arrangements of the present disclosure. In some arrangements, FIG. 1C shows a top view of the package structure 1 illustrated in FIG. 1A. In some arrangements, FIG. 1A shows a cross-section along a line 1A-1A′ in FIG. 1C. The package structure 1C illustrated in FIG. 1C is similar to that in FIG. 1B, with differences therebetween as follows.

In some arrangements, the adhesive layer 30 surrounds the chip 20. In some arrangements, the gap G1 surrounds the chip 20. In some arrangements, the portion 110A of the circuit layer 110 surrounds the chip 20, the adhesive layer 30, and the gap G1. In some arrangements, the dielectric layer 120 has multiple openings 120T adjacent to the surfaces 203, 204, 205, and 206 of the chip 20, respectively. In some arrangements, the portion 110A includes multiple segments partially exposed by the multiple openings 120T, respectively. In some arrangements, the spacer structure 50 includes multiple segments disposed on the respective exposed segments of the portion 110A. In some arrangements, the adhesive element 51 includes multiple segments connecting the segments of the spacer structure 50 to the respective exposed segments of the portion 110A.

FIG. 1D is a bottom view of a package structure 1D in accordance with some arrangements of the present disclosure. In some arrangements, FIG. 1D shows a bottom view of the package structure 1 illustrated in FIG. 1A. In some arrangements, FIG. 1A shows a cross-section along a line 1A-1A′ in FIG. 1D.

In some arrangements, the protective element 70 encapsulates the conductive wire 42 and a portion of the pad 220. In some arrangements, the protective element 70 further covers at least a portion of the protective film 170B and a portion of the adhesive layer 30.

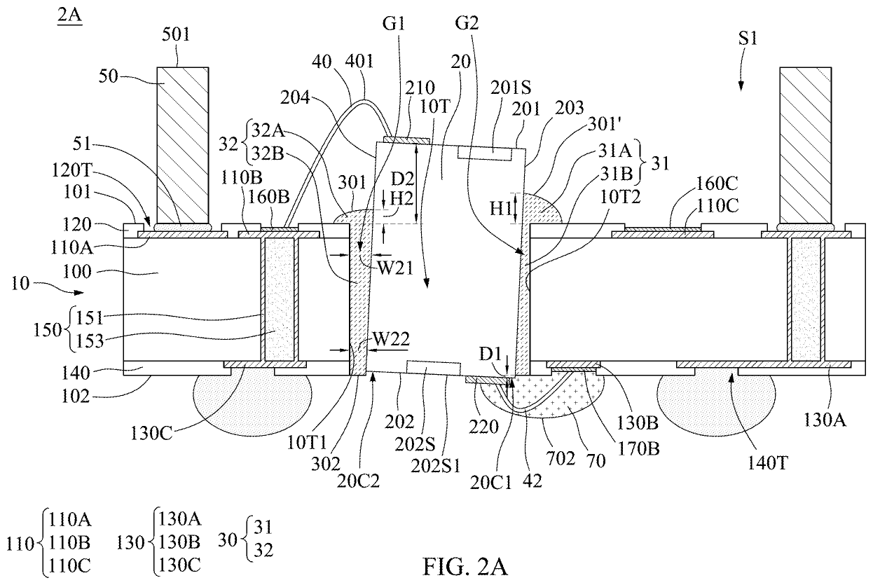

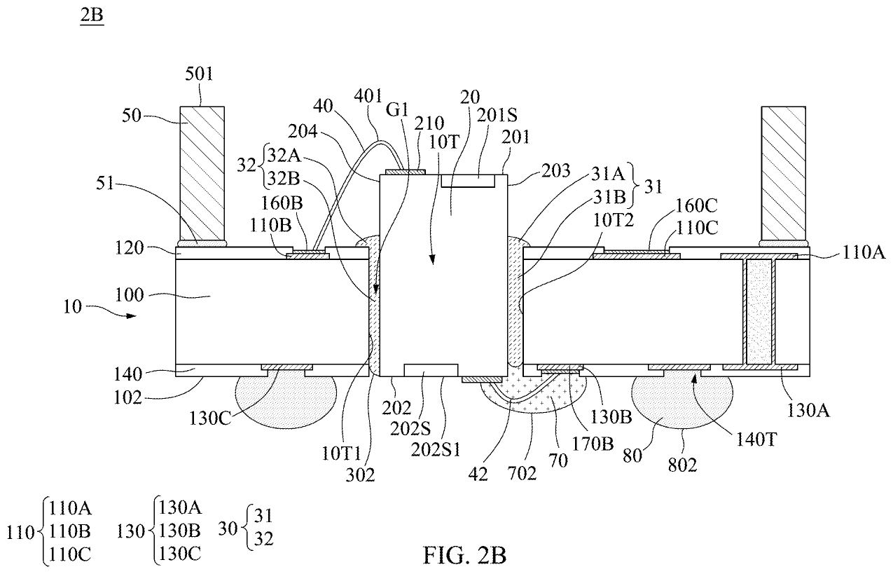

FIG. 2A is a cross-section of a package structure 2A in accordance with some arrangements of the present disclosure. The package structure 2A illustrated in FIG. 2A is similar to that in FIG. 1A, with differences therebetween as follows. In some arrangements, the package structure 2A may have a structure as shown in FIG. 1B or FIG. 1C from a top view perspective.

In some arrangements, the surface 203 of the chip 20 is inclined with respect to the sidewall 10T1 of the through hole 10T of the substrate 10. In some arrangements, the surface 204 of the chip 20 is inclined with respect to the sidewall 10T2 of the through hole 10T of the substrate 10. In some arrangements, the portion 31 and the portion 32 of the adhesive layer 30 taper toward opposite directions in a cross-sectional view perspective. In some arrangements, an elevation of the surface 202S1 of the sensing element 202S is lower than the elevation of the surface 102 (or the bottom surface) of the substrate 10 with respect to the surface 101 (or the top surface).

In some arrangements, an upper portion and a lower portion of the gap G1 have different widths. In some arrangements, a width W21 of the upper portion of the gap G1 is different from a width W22 of the lower portion of the gap G1. In some arrangements, in a cross-sectional view perspective, a gap G2 is at an opposite side of the chip 20 to the gap G1, and the gap G1 and the gap G2 taper toward opposite directions.

In some arrangements, the chip 20 includes corner portions 20C1 and 20C2. In some arrangements, the corner portion 20C1 of the chip 20 is lower than an elevation of the surface 102 (or the bottom surface) of the substrate 10 with respect to the surface 101 (or the top surface), and the corner portion 20C2 of the chip 20 is higher than the elevation of the surface 102 of the substrate 10 with respect to the surface 101. In some arrangements, an elevation of the surface 102 (or the bottom surface) of the substrate 10 is between an elevation of the corner portion 20C1 and an elevation of the corner portion 20C2. In some arrangements, a vertical distance D2 between the pad 210 and the surface 101 of the substrate 10 is greater than a vertical distance D1 between the pad 220 and the surface 102 of the substrate 10.

In some arrangements, the adhesive layer 30 is disposed in the gap G1 within the through hole 10T. In some arrangements, the adhesive layer 30 is filled completely filled in the gap G1. In some arrangements, the adhesive layer 30 includes an upper portion and a lower portion having different thicknesses (or widths). In some arrangements, a thickness or width (e.g., the width W21) of the upper portion of the adhesive layer 30 is different from a thickness or width (e.g., the width W22) of the lower portion of the adhesive layer 30. In some arrangements, the adhesive layer includes parts (e.g., upper parts 31A and 32A) protruded out of the through hole and parts (e.g., lower parts 31B and 32B) in the through hole 10T. In some arrangements, the width W3 of the upper part 31A is greater than the width W1 of the lower part 31B, and the width W4 of the upper part 32A is greater than the width W2 of the lower part 32B. In some arrangements, in a cross-sectional view perspective, the upper part 31A and the upper part 32A are opposite sides of the chip 20, the upper part 31A is protruded beyond the surface 101 of the substrate by a height H1, and the upper part 32A is protruded beyond the surface 101 of the substrate 10 by a height H2 different from the height H1.

FIG. 2B is a cross-section of a package structure 2B in accordance with some arrangements of the present disclosure. The package structure 2A illustrated in FIG. 2A is similar to that in FIG. 1A, with differences therebetween as follows.

In some arrangements, the spacer structure 50 is adhered to the dielectric layer 120 of the substrate 10 through the adhesive element 51. In some arrangements, the adhesive element 51 is or includes an insulating adhesive material. In some arrangements, the spacer structure 50 may include a dielectric material, a conductive material, or any suitable spacer materials. In some arrangements, the spacer structure 50 is not electrically connected to ground or any conductive structure.

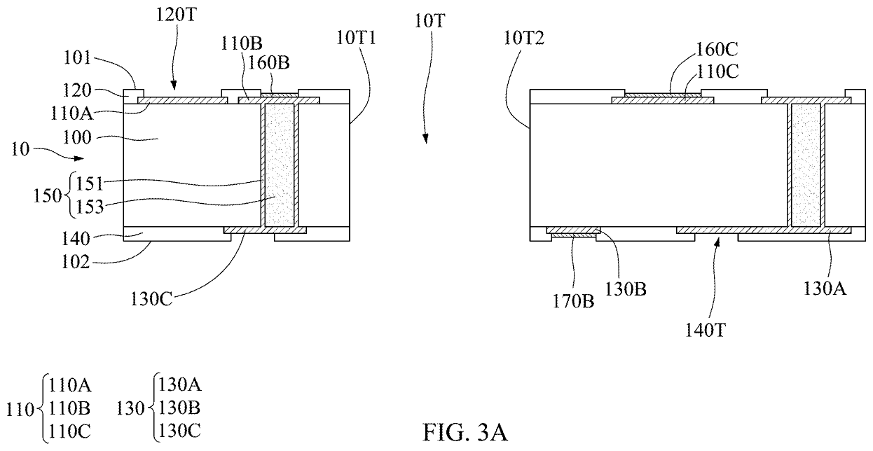

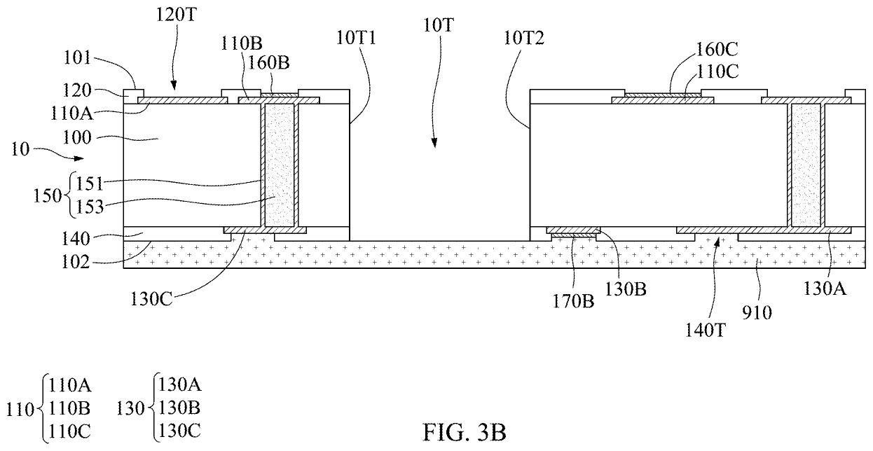

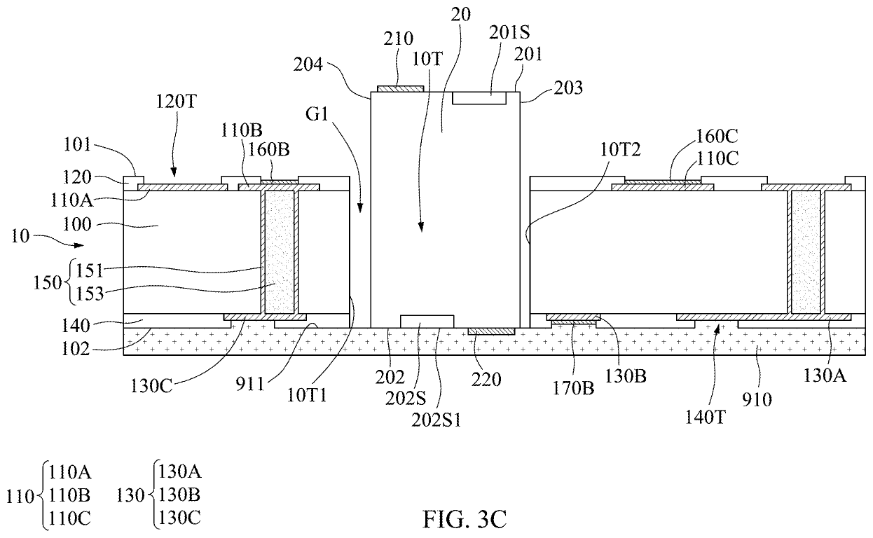

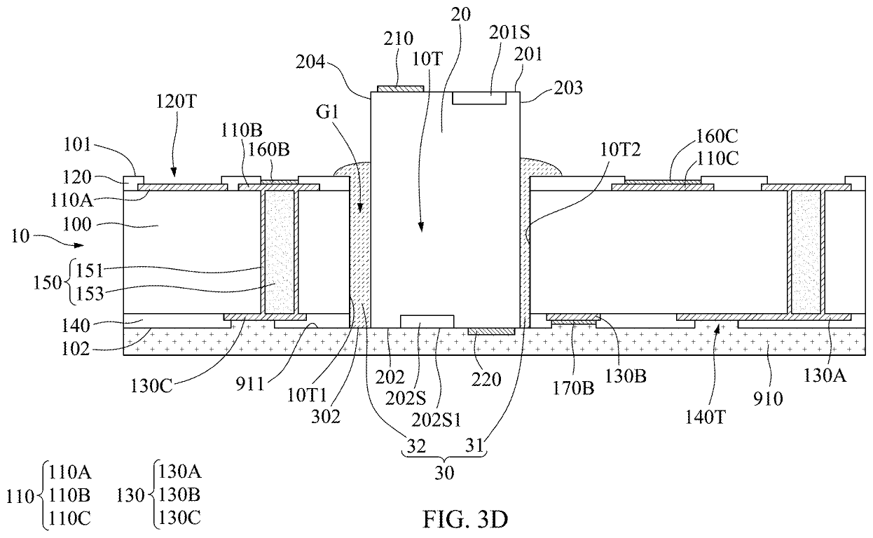

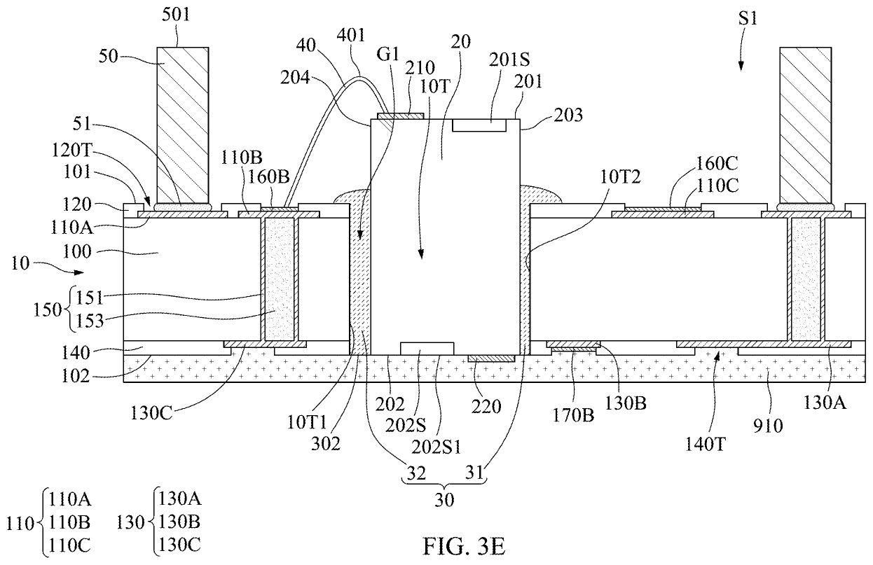

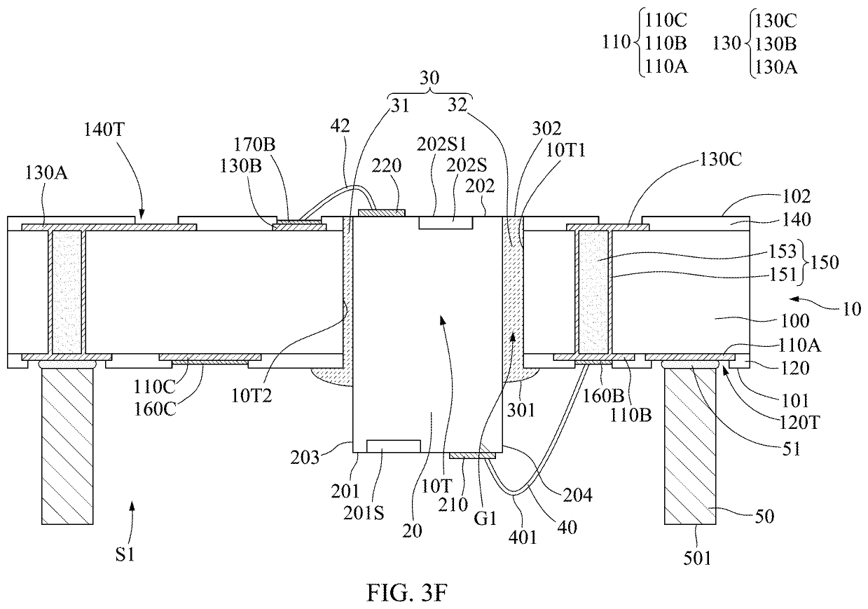

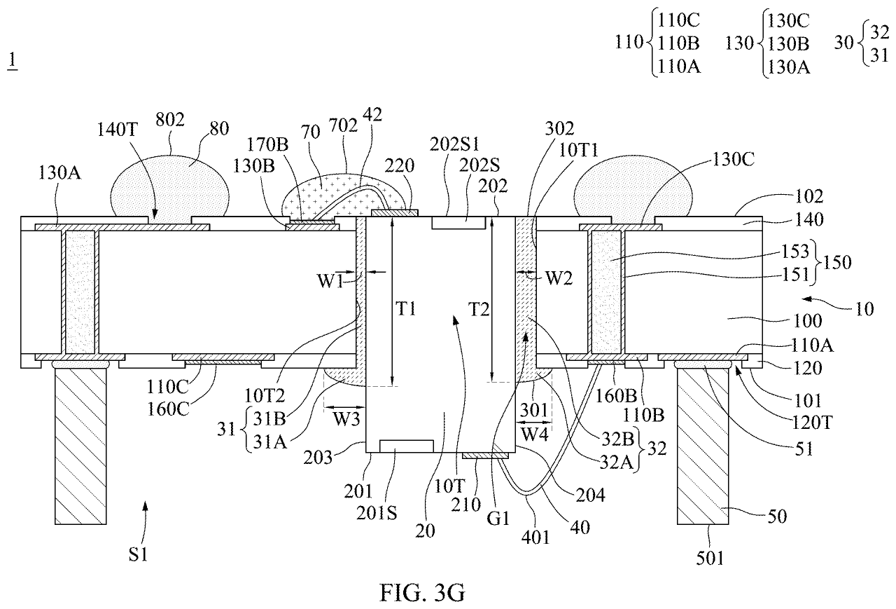

FIG. 3A, FIG. 3B, FIG. 3C, FIG. 3D, FIG. 3E, FIG. 3F, and FIG. 3G illustrate various stages of an exemplary method for manufacturing a package structure 1 in accordance with some embodiments of the present disclosure.

Referring to FIG. 3A, a substrate 10 including a base layer 100, circuit layers 110 and 130, dielectric layers 120 and 140, and one or more conductive vias 150 may be provided. A through hole 10T may be formed penetrating the base layer 100 and the dielectric layers 120 and 140. The through hole 10T may be formed by laser drilling, mechanical drilling, or any suitable technique.

Referring to FIG. 3B, the substrate 10 may be adhered to a temporary carrier 910. In some arrangements, the temporary carrier 910 may be or include an adhesive film, e.g., a release film or a tape. The temporary carrier 910 may be flexible and relatively soft. The temporary carrier 910 may deform upon pressure. In some arrangements, portions of the temporary carrier 910 may deformed and at least partially fill in the openings 140T of the dielectric layer 140.

Referring to FIG. 3C, a chip 20 including pads 210 and 220 may be disposed in the through hole 10T on the temporary carrier 910. In some arrangements, the surface 101 of the substrate 10 and the surface 202 of the chip 20 may contact a top surface 911 of the temporary carrier 910. In some arrangements, the surface 101 of the substrate 10 may be substantially aligned with the surface 202 of the chip 20. In some arrangements, the pad 220 may protrude into the temporary carrier 910. In some arrangements, the chip 20 may be separated from the sidewall of the through hole 10T by a gap G1.

Referring to FIG. 3D, an adhesive material may be filled into the gap G1, and a curing operation may be performed to the adhesive material to form an adhesive layer 30 at least partially in the gap G1. In some arrangements, a portion of the adhesive material may overflow toward outside of the gap G1 (or the through hole 10T) to cover a portion of the surface 101 of the substrate 10. In some arrangements, the adhesive material directly contacts the top surface 911 of the temporary carrier 910. In some arrangements, the surface 101 of the substrate 10 and the surface 202 of the chip 20 may be substantially aligned with a bottom surface of the adhesive material. In some arrangements, the surface 101 of the substrate 10 and the surface 202 of the chip 20 may be substantially aligned with a bottom surface (e.g., the surface 302) of the adhesive layer 30 after the curing operation is completed.

Referring to FIG. 3E, a conductive wire 40 may be provided or formed over the surface 101 of the substrate 10 to connect the circuit layer 110 to the pad 210 of the chip 20, and a spacer structure 50 may be adhered or attached to the substrate 10. In some arrangements, the spacer structure 50 is adhered to the portion 110A of the circuit layer 110 by an adhesive element 51 exposed by the opening 120T of the dielectric layer 120.

Referring to FIG. 3F, the structure illustrated in FIG. 3E may be flipped over, such that the spacer structure 50 may serve as a temporary supporting carrier for the structure to undergo subsequent operations. Next, a conductive wire 42 may be provided or formed over the surface 102 of the substrate 10 to connect the circuit layer 130 to the pad 220 of the chip 20.

Referring to FIG. 3G, a protective element 70 may be formed to encapsulate the conductive wire 42, and electrical contacts 80 may be disposed or formed on the surface 102 of the substrate 10. In some arrangements, the protective element 70 may be formed by a one drop filling (ODF) process. In some arrangements, the protective element 70 may be or include a sealing gel. In some arrangements, the protective element 70 may be or include a sealant. As such, the package structure 1 illustrated in FIG. 1A may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a substrate defining a through hole;
a chip disposed in the through hole, the chip having a top surface and a bottom surface opposite to the top surface; and
an adhesive layer connecting the chip to the through hole, wherein the top surface and the bottom surface of the chip are exposed by the adhesive layer, and the chip is protruded beyond the substrate.

2. The package structure as claimed in claim 1, wherein the chip comprises a first sensing element adjacent to the top surface of the chip and a second sensing element adjacent to the bottom surface of the chip.

3. The package structure as claimed in claim 2, wherein the first sensing element or the second sensing element is exposed by the adhesive layer.

4. The package structure as claimed in claim 3, wherein the bottom surface of the chip is substantially aligned with a bottom surface of the adhesive layer.

5. The package structure as claimed in claim 4, wherein at least one of the first sensing element and the second sensing element is an acoustic sensor.

6. The package structure as claimed in claim 1, further comprising:
a wire-bonding structure connecting at least one of the top surface and the bottom surface of the chip to a surface of the substrate; and
a protective structure configured to prevent the wire-bonding structure from impacts from outside of the package structure.

7. The package structure as claimed in claim 6, wherein the protective structure and the surface of the substrate collectively define a space, and the top surface of the chip is exposed to the space, and a top end of the wire-bonding structure is lower than a top surface of the protective structure.

8. A package structure, comprising:
a substrate defining a through hole; and
a chip disposed in the through hole, wherein a first gap between the chip and a sidewall of the through hole comprises an upper portion and a lower portion having different widths.

9. The package structure as claimed in claim 8, wherein the substrate has a top surface and a bottom surface opposite to the top surface, a first corner portion of the chip is lower than an elevation of the bottom surface of the substrate with respect to the top surface, and a second corner portion of the chip is higher than the elevation of the bottom surface of the substrate with respect to the top surface.

10. The package structure as claimed in claim 9, wherein the chip comprises a sensing element adjacent to a bottom surface of the chip, and an elevation of a surface of the sensing element is lower than the elevation of the bottom surface of the substrate with respect to the top surface.

11. The package structure as claimed in claim 8, wherein in a cross-sectional view perspective, a second gap is at an opposite side of the chip to the first gap, the first gap tapers toward a first direction, and the second gap tapers toward a second direction opposite to the first direction.

12. The package structure as claimed in claim 8, further comprising an adhesive layer disposed in the first gap within the through hole.

13. The package structure as claimed in claim 12, wherein the adhesive layer is filled in the first gap.

14. The package structure as claimed in claim 12, wherein the adhesive layer comprises a first part protruded out of the through hole and a second part in the through hole.

15. The package structure as claimed in claim 14, wherein a width of the first part of the adhesive layer is greater than a width of the second part of the adhesive layer.

16. A package structure, comprising:
a substrate defining a through hole extending between a top surface and a bottom surface of the substrate; and
a chip disposed in the through hole, the chip having a top surface and a bottom surface opposite to the top surface, wherein the top surface of the chip is protruded beyond the top surface of the substrate, and the bottom surface of the chip is substantially aligned with the bottom surface of the substrate.

17. The package structure as claimed in claim 16, further comprising a first wire connecting a first pad of the chip to the top surface of the substrate and a second wire connecting a second pad of the chip to the bottom surface of the substrate, wherein a curvature change of the first wire is greater than a curvature change of the second wire.

18. The package structure as claimed in claim 16, further comprising an adhesive layer around the chip.

19. The package structure as claimed in claim 18, wherein the adhesive layer (30) comprises a first part in the through hole and a second part extending over at least a portion of the top surface of the substrate.

20. The package structure as claimed in claim 19, wherein the second part of the adhesive layer has a curved surface in a cross-sectional view perspective.
